(19) United States
(12) Patent Application Publication
(10) Pub. No.: US 2021/0111368 A1
(43) Pub. Date: Apr. 15, 2021

(54) LIGHT-EMITTING DEVICE AND ELECTRONIC APPARATUS

(71) Applicant: SEIKO EPSON CORPORATION, Tokyo (JP)

(72) Inventor: Takumi KODAMA, SUWA-SHI (JP)

(73) Assignee: SEIKO EPSON CORPORATION, Tokyo (JP)

(21) Appl. No.: 17/069,820

(22) Filed: Oct. 13, 2020

(30) Foreign Application Priority Data
Oct. 15, 2019 (JP) 2019-188447

(51) Int. Cl. H01L 51/52; G02B 27/01

(52) U.S. Cl. CPC H01L 51/5246; H01L 27/322; G02B 27/0172

(57) ABSTRACT

An organic EL device includes an element substrate, an organic EL element formed on the element substrate, a protective substrate covering the organic EL element, and a filling layer that bonds the protective substrate and the element substrate, wherein, in plan view, three sides of an outer edge of the protective substrate are arranged so as not to overlap with the element substrate.

The present application is based on, and claims priority from JP Application Serial Number 2019-188447, filed Oct. 15, 2019, the disclosure of which is hereby incorporated by reference herein in its entirety.

### BACKGROUND

### 1. Technical Field

The present disclosure relates to a light-emitting device and an electronic apparatus.

### 2. Related Art

Typically, a light-emitting device is known which includes a protective glass for protecting a color filter and the like on an organic EL (electro luminescence) element substrate. The protective glass is arranged with respect to the color filter via a filling layer and the like. For example, JP-A-2015-207551 discloses an organic EL device in which a sealing substrate is arranged as a protective glass so as to cover an organic EL element and the like.

However, in the organic EL device of JP-A-2015-207551, there is a problem that when a glass sheet is generated from a cut surface of the sealing substrate, a wiring short-circuit failure of the organic EL element and the like is easy to occur. Specifically, in a typical organic EL device, three sides of an outer edge of the sealing substrate are arranged to overlap three sides of an outer edge of the element substrate. Therefore, when each sealing substrate is divided from a large sheet in the process of manufacturing the organic EL device, when a glass sheet is generated from the outer edge of the sealing substrate and the like, the glass sheet may be sandwiched between the filling layer and the sealing substrate. In this case, when crimping the sealing substrate and the element substrate, the glass sheet penetrates the filling layer, causing a crack and the like in a color filter or a lower wiring layer, inducing a wiring short-circuit failure. In other words, there is a demand for a light-emitting device that suppresses the occurrence of defects due to the glass sheet of the protective glass.

### SUMMARY

A light-emitting device includes a substrate, a light-emitting element arranged at the substrate a protective glass covering the light-emitting element, and a filling layer that bonds the protective glass and the substrate, wherein, three sides of an outer edge of the protective glass are arranged so as not to overlap the substrate in plan view.

In the light-emitting device described above, the protective glass may include a housing portion that houses the light-emitting element, and the housing portion may include the wall portion corresponding to three sides of the protective glass.

In the light-emitting device described above, the wall portion extends along the normal line direction of the substrate, and when viewed as a side from a direction orthogonal to the normal line direction, the bottom end of the wall portion may be positioned on the side of the bottom surface opposite to the surface on which the light-emitting element is formed than the surface on which the light-emitting element is formed.

In the light-emitting device described above, in side view, the lower end of the wall portion may be separated from the bottom surface with respect to the surface on which the light-emitting element is formed on the substrate.

A light-emitting device includes a substrate, a light-emitting element arranged at the substrate, a protective glass covering the light-emitting element, and a filling layer that bonds the protective glass and the substrate, wherein, the protective glass includes a housing part that houses the light-emitting element, the housing part includes a wall portion corresponding to the three sides of the outer edge of the protective glass in plan view, the wall portion extends along a thickness direction of the substrate, a lower end of the wall portion is provided with a convex pattern, a concave pattern that fits the convex pattern is provided at a surface of the substrate at which the light-emitting element is arranged.

In the light-emitting device described above, the concave pattern may be formed from the same material as a material of the substrate.

An electronic apparatus according to the present disclosure includes the light-emitting device described above.

### BRIEF DESCRIPTION OF THE DRAWINGS

FIG. 1 is a schematic plan view illustrating a configuration of an organic EL device as a light-emitting device according to a first embodiment.

FIG. 2 is an equivalent circuit diagram illustrating an electrical configuration of a light-emitting pixel of the organic EL device.

FIG. 3 is a schematic plan view illustrating a configuration of the light-emitting pixel of the organic EL device.

FIG. 4 is a schematic cross-sectional view illustrating the configuration of the organic EL device.

FIG. 5 is a perspective view illustrating the appearance of a protective glass.

FIG. 6 is a schematic plan view illustrating a configuration of an organic EL device according to a second embodiment.

FIG. 7 is a schematic cross-sectional view illustrating the configuration of the organic EL device.

FIG. 8 is a schematic diagram illustrating a head-mounted display as an electronic apparatus according to a third embodiment.

FIG. 9 is a schematic cross-sectional view illustrating a configuration of an organic EL device as a light-emitting device according to a first modified example.

### DESCRIPTION OF EXEMPLARY EMBODIMENTS

### 1. First Embodiment

In the present embodiment, an organic EL (electro luminescence) device is exemplified as a light-emitting device. This light-emitting device can be suitably used, for example, in a Head Mounted Display (HMD) as an electronic apparatus described below.

Note that, in the following drawings, XYZ axes are given as coordinate axes that are orthogonal to each other as necessary, a direction indicated by an arrow is defined as a +direction, and a direction opposite the +direction is defined as a −direction. Note that the +Z direction may be referred to as an upper side and the −Z direction may be referred to as a lower side, and the view from the +Z direction may be referred to as a plan view or a planar. Furthermore, in the following description, for example, a description of “on a substrate” with respect to a substrate refers to any one of a case of being arranged in contact with an upper side of the substrate, a case of being arranged on the upper side of the substrate via another structure, or a case where a part is arranged in contact with the upper side of the substrate and a case where a part is arranged on the upper side of the substrate via another structure.

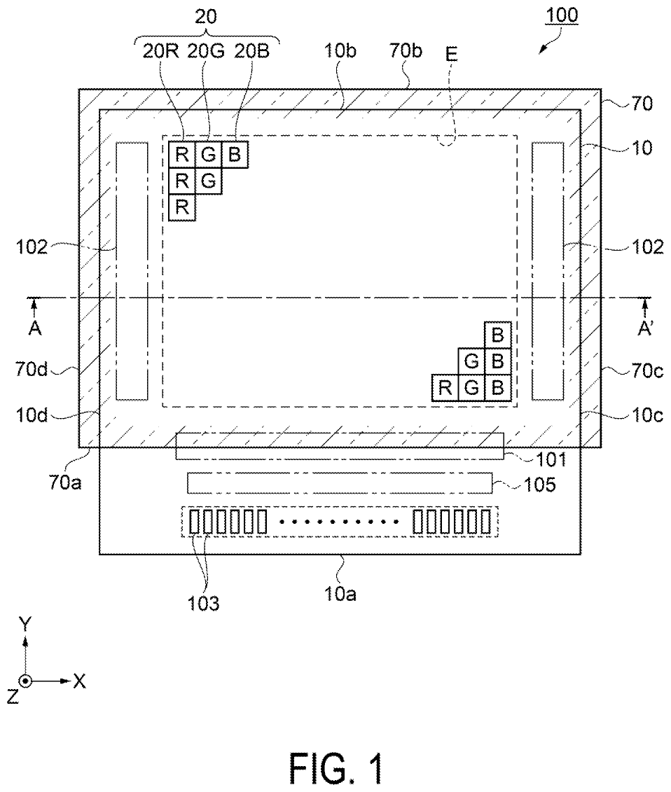

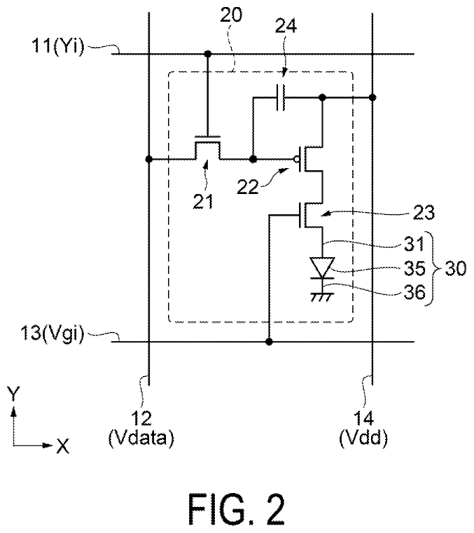

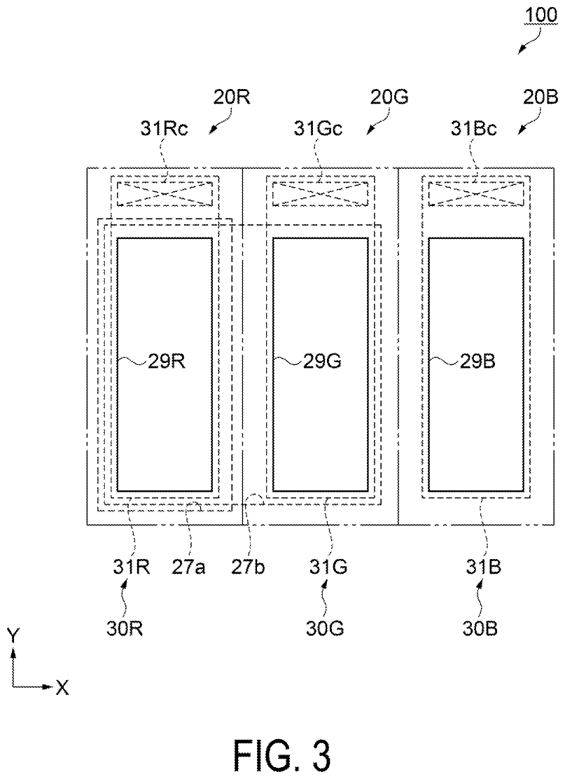

A planar configuration of the organic EL device as a light-emitting device according to the present embodiment will be described with reference to FIG. 1 to FIG. 3. FIG. 1 is a schematic plan view illustrating a configuration of an organic EL device as a light-emitting device according to a first embodiment. FIG. 2 is an equivalent circuit diagram illustrating an electrical configuration of a light-emitting pixel of the organic EL device. FIG. 3 is a schematic plan view illustrating a configuration of the light-emitting pixel the organic EL device.

As illustrated in FIG. 1, an organic EL device 100 as a light-emitting device includes an element substrate 10 as a substrate, a plurality of light-emitting pixels 20, a protective glass 70, a data line driving circuit 101, a pair of scan line driving circuits 102, a control circuit 105, and a plurality of external connection terminals 103. Here, in FIG. 1, with respect to the element substrate 10, the vicinity of an outer edge of the protective glass 70 arranged above is shown by hatching, and the protective glass 70 is shown transparent.

The element substrate 10 is substantially rectangular in plan view, and has four sides of the outer edge, a first side portion 10a, a second side portion 10b, a third side portion 10c, and a fourth side portion 10d. The first side portion 10a and the second side portion 10b are along the X axis and opposite to each other in the ±Y direction. The first side portion 10a is a side closer to the −Y direction among the four sides of the outer edge. The second side portion 10b is a side closer to the +Y direction among the four sides of the outer edge. The third side portion 10c and the fourth side portion 10d are along the Y axis and opposite to each other in the ±X direction. The third side portion 10c is a side closer to the +X direction among the four sides of the outer edge. The fourth side portion 10d is a side closer to the −X direction among the four sides of the outer edge.

The protective glass 70 is substantially rectangular in plan view, and has four sides of the outer edge, a first side portion 70a, a second side portion 70b, a third side portion 70c, and a fourth side portion 70d. The first side portion 70a and the second side portion 70b are along the X axis and opposite to each other in the ±Y direction. The first side portion 70a is a side closer to the −Y direction among the four sides of the outer edge. The second side portion 70b is a side closer to the +Y direction among the four sides of the outer edge. The third side portion 70c and the fourth side portion 70d are along the Y axis and opposite to each other in the ±X direction. The third side portion 70c is a side closer to the +X direction among the four sides of the outer edge. The fourth side portion 70d is a side closer to the −X direction among the four sides of the outer edge.

The protective glass 70 is arranged covering a display region E. In plan view, three sides of the outer edge of the protective glass 70 are arranged so as not to overlap with the element substrate 10. Specifically, in plan view, the second side portion 70b of the protective glass 70 is arranged protruding outward beyond the second side portion 10b of the element substrate 10, the third side portion 70c of the protective glass 70 is arranged protruding outward beyond the third side portion 10c of the element substrate 10, and the fourth side portion 70d of the protective glass 70 is arranged protruding outward beyond the fourth side portion 10d of the element substrate 10. Three sides of the protective glass 70 arranged so as not to overlap with the element substrate 10 are the second side portion 70b, the third side portion 70c, and the fourth side portion 70d.

In contrast, the first side portion 10a of the element substrate 10 protrudes outward beyond the first side portion 70a of the protective glass 70 in a plan view. Therefore, a part of the data line driving circuit 101, the control circuit 105, and the external connection terminal 103 arranged on the element substrate 10 are not covered with the protective glass 70 in plan view and are exposed upward.

The plurality of light-emitting pixels 20 are arranged in a matrix in the display region E of the element substrate 10. The data line driving circuit 101 and The pair of scan line driving circuits 102 are peripheral circuits configured to drive and control the plurality of the light-emitting pixels 20. The peripheral circuit is electrically coupled to the plurality of the external connection terminals 103 via the control circuit 105. The control circuit 105 controls the display image. Then, the plurality of external connection terminals 103 are electrically coupled to an external circuit (not illustrated). The organic EL device 100 of the present embodiment is an active driven and top-emitting type light-emitting device.

In the display region E, a light-emitting pixel 20R that can obtain a light emission of a red color (R), a light-emitting pixel 20G that can obtain a light emission of a green color (G), and a light-emitting pixel 20B that can obtain a light emission of a blue color (B) are arranged. Further, the light-emitting pixels 20, that can obtain the light emission of the same color, are arranged along the +Y direction, which is the vertical direction in FIG. 1. The light-emitting pixels 20, that can obtain light emissions with different colors, are arranged along the +X direction, which is the horizontal direction in FIG. 1 in an order of R, G, B.

The arrangement of such light-emitting pixels 20 is referred to as a stripe method. The arrangement of the light-emitting pixels 20 is not limited to this. For example, the arrangement in the horizontal direction of the light-emitting pixels 20 that can obtain light emissions with different colors may not be in the order of R, G, B, and may be, for example, in order of B, G, R. Note that the direction in which light is emitted from the light-emitting pixel 20 is the +Z direction and coincides with the normal direction of the element substrate 10.

A detailed configuration of the light-emitting pixel 20 is described below, but each of the light-emitting pixels 20R, 20G, 20B in the present embodiment includes an organic EL element as a light-emitting element, and a color filter corresponding to each color of R, G, B. The color filter converts the light emission of the organic EL element into each color of R, G, B, and performs a full color display. Further, in the emission wavelength range of light emitted from the organic EL element, an optical resonance structure for improving the luminance of light having a specific wavelength is constructed for each of the light-emitting pixels 20R, 20G, 20B.

Each of the plurality of light-emitting pixels 20R, 20G, 20B functions as a sub-pixel. In other words, the organic EL device 100 includes a plurality of the light-emitting pixels 20R, 20G, 20B, which are a plurality of the sub-pixels arranged in the +X direction and the +Y direction of the display region E.

One pixel unit in the image display is constituted by three light-emitting pixels 20R, 20G, 20B that emit light corresponding to the R, G, B. Note that the configuration of the pixel unit is not limited to this, and light-emitting pixels 20, in which a light emission color including white, other than R, G, B, can be obtained may be included in the pixel unit.

The plurality of external connection terminals 103 are arranged in the +X direction along the first side portion 10a of the element substrate 10. The data line driving circuit 101 is arranged between the external connection terminal 103 and the display region E in the +Y direction and extends along the X axis. A control circuit 105 is arranged between the data line driving circuit 101 and the external connection terminal 103. The pair of scan line driving circuits 102 are disposed sandwiching the display region E in the ±X direction. The pair of scan line driving circuits 102 are arranged along the third side portion 10c and the fourth side portion 10d of the element substrate 10, respectively.

Here, although not illustrated, a plurality of wiring lines connecting the pair of scan line driving circuits 102 are disposed between the display region E and the second side portion 10b of the element substrate 10. Further, an inspecting circuit may also be provided between the display region E and the second side portion 10b of the element substrate 10. The inspection circuit may be electrically coupled to a data line to be described below, and the operation check using the inspection circuit may be performed in the manufacturing process of the organic EL device 100.

As described above, a plurality of light-emitting pixels 20 are disposed in a matrix in the display region E. As illustrated in FIG. 2, in the element substrate 10, a scan line 11, a data line 12, a lighting enable line 13, and a power supply line 14 are disposed as signal lines corresponding to the light-emitting pixel 20. In the present embodiment, the scan line 11 and the lighting enable line 13 extend along the X axis, and the data line 12 and the power supply line 14 extend along the Y axis. Note that in the following description of FIG. 2, which is an equivalent circuit diagram, being electrically coupled is also referred to as simply coupled.

In the display region E, a plurality of scan lines 11 and a plurality of lighting enable lines 13 are disposed in the display region E corresponding to the m rows of the plurality of light-emitting pixels 20 arranged in a matrix. The plurality of the scan lines 11 and the plurality of the lighting enable lines are respectively coupled to the pair of scan line driving circuits 102 illustrated in FIG. 1. In addition, a plurality of data lines 12 and a plurality of power supply lines 14 are disposed corresponding to the n columns of the plurality of light-emitting pixels 20 arranged in a matrix. The plurality of the data lines 12 are respectively coupled to the data line driving circuit 101 illustrated in FIG. 1. The plurality of power supply lines 14 are coupled to any of the plurality of the external connection terminals 103.

In the vicinity of an intersection of the scan line 11 and the data line 12, a first transistor 21, a second transistor 22, a third transistor 23, a storage capacitor 24, and an organic EL element 30 as a light-emitting element, which constitute a pixel circuit of the light-emitting pixel 20, are disposed.

The organic EL element 30 includes a pixel electrode 31 that is an anode, a cathode 36, and a function layer 35 sandwiched therebetween, including a light-emitting layer. The cathode 36 is an electrode disposed in common over the plurality of the light emitting pixels 20, and is applied with a potential of a lower reference potential Vss or GND (ground) with respect to the power supply voltage Vdd applied to the power supply line 14.

The first transistor 21 and the third transistor 23 are, for example, n-channel type transistors. The second transistor 22 is, for example, a p-channel type transistor.

In the first transistor 21, the gate electrode is coupled to the scan line 11, one current end is coupled to the data line 12, and the other current end is coupled to the gate electrode of the second transistor 22 and one electrode of the storage capacitor 24.

One current end of the second transistor 22 is coupled to the power supply line 14 and is coupled to the other electrode of the storage capacity 24. The other current end of the second transistor 22 is coupled to one current end of the third transistor 23. In other words, the second transistor 22 and the third transistor 23 share one current end of the pair of current ends.

In the third transistor 23, the gate electrode is coupled to the lighting enable line 13, and the other current end is coupled to the pixel electrode 31 of the organic EL element 30. One of the pair of current ends in each of the first transistor 21, the second transistor 22, and the third transistor 23 is a source and the other is a drain.

In such a pixel circuit, when the voltage level of the scan signal Yi supplied from the scan line driving circuit 102 to the scan line 11 is at High level, the first transistor 21 of the n-channel type is turned to the ON-state (ON). The data line 12 and the storage capacity 24 are electrically coupled via the first transistor 21 in the ON-state (ON). Then, when the data signal is supplied from the data line driving circuit 101 to the data line 12, a potential difference between the voltage level Vdata of the data signal and the power supply voltage Vdd applied to the power supply line 14 is accumulated in the storage capacity 24.

When the voltage level of the scan signal Yi supplied from the scan line driving circuit 102 to the scan line 11 is at Low level, the first transistor 21 of the n-channel type is turned to the OFF-state (OFF). Thus, the voltage Vgs between the gate and the source of the second transistor 22 is held at a voltage when the voltage level Vdata is applied. Further, after the scan signal Yi becomes the Low level, the voltage level of the lighting enable signal Vgi supplied to the lighting enable line 13 becomes High level, and the third transistor 23 is turned to the ON-state (ON). In this way, a current corresponding to the voltage Vgs between the gate and the source of the second transistor 22 flows between the source and the drain of the second transistor 22. Specifically, this current flows in a path from the power supply line 14 to the organic EL element 30 via the second transistor 22 and the third transistor 23.

The organic EL element 30 emits light in accordance with the magnitude of the current flowing in the organic EL element 30. The current flowing in the organic EL element 30 is determined by the second transistor 22 configured by the voltage Vgs between the gate and the source of the second transistor 22, and an operating point of the organic EL element 30. The voltage Vgs between the gate and the source of the second transistor 22 is the voltage held in the storage capacity 24 by the voltage difference between the voltage level Vdata of the data line 12 and the power supply voltage Vdd when the scan signal Yi is at the High level. In this manner, in the light-emitting pixel 20, the light emission luminance is defined by the voltage level Vdata in the data signal and the length of the period in which the third transistor 23 is turned to the ON-state. In other words, by the value of the voltage level Vdata in the data signal, in the light-emitting pixel 20, it is possible to provide a gradation of luminance according to image information.

Here, the pixel circuit of the light-emitting pixel 20 is not limited to include three transistors 21, 22, 23, and may be configured to include a transistor for switching and a transistor for driving. In addition, the transistor that constitutes the pixel circuit may be an n-channel type transistor, a p-channel type transistor, or a transistor including both the n-channel type transistor and the p-channel type transistor. Furthermore, the transistor that constitutes the pixel circuit of the light-emitting pixel 20 may be a metal-oxide semiconductor (MOS) field effect transistor including an active layer on a semiconductor substrate, a thin film transistor, or a field effect transistor.

As illustrated in FIG. 3, each of the light-emitting pixels 20R, 20G, 20B is rectangular in plan view, and the longitudinal direction is arranged along the Y axis. The organic EL element 30 of an equivalent circuit illustrated in FIG. 2 is disposed in each of the light-emitting pixels 20R, 20G, 20B. Here, in order to distinguish the organic EL element 30 disposed for each of the light-emitting pixels 20R, 20G, 20B, sometimes the organic EL element 30 may be described as the organic EL element 30R, 30G, 30B. Further, in order to distinguish the pixel electrode 31 of the organic EL element 30 for each of the light-emitting pixels 20R, 20G, 20B, the pixel electrode 31 may be described as the pixel electrode 31R, 31G, 31B.

In the light-emitting pixel 20R, a pixel electrode 31R and a contact portion 31Rc that electrically couples the pixel electrode 31R and the third transistor 23, are disposed. Similarly, in the light-emitting pixel 20G, a pixel electrode 31G and a contact portion 31Gc that electrically couples the pixel electrode 31G and the third transistor 23, are disposed. In the light-emitting pixel 20B, a pixel electrode 31B and a contact portion 31Bc that electrically couples the pixel electrode 31B and the third transistor 23, are disposed. The pixel electrodes 31R, 31G, 31B are substantially rectangular in plan view, and the contact portions 31Rc, 31Gc, 31Bc are arranged on the +Y direction side in the longitudinal direction, respectively.

The light-emitting pixels 20R, 20G, 20B has an opening 29R, 29G, 29B, respectively. The opening 29R, 29G, 29B is an insulating structure that electrically insulates adjacent pixel electrodes 31 from each other, and defines a region that is in contact with a function layer described below, on the pixel electrodes 31R, 31G, 31B. In the present embodiment, the shapes and sizes of the openings 29R, 29G, 29B are the same.

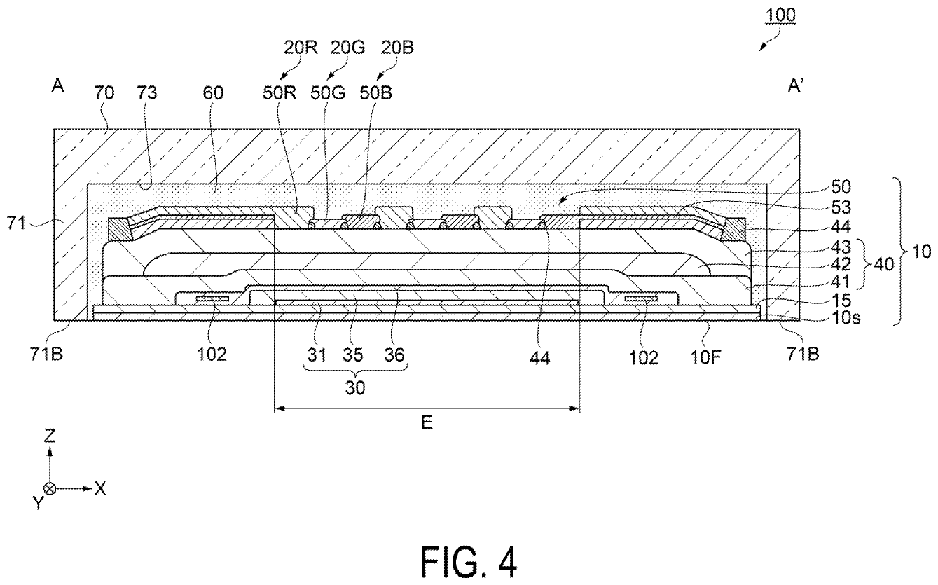

Next, a cross-sectional configuration of the organic EL device 100 will be described with reference to FIG. 4. FIG. 4 is a schematic cross-sectional view illustrating the configuration of the organic EL device. Note that, FIG. 4 illustrates a cross section taken along the XZ plane including line A-A′ in FIG. 1, and is a cross-sectional view when viewed from the −Y direction orthogonal to the normal line direction of the element substrate 10. In addition, in FIG. 4, for convenience of illustration, the number of light-emitting pixels 20 is smaller than the actual number, and the display region E is smaller than the actual size. Furthermore, in FIG. 4, the illustration of the first transistor 21, the second transistor 22, and the third transistor 23 are omitted.

As illustrated in FIG. 4, the organic EL device 100 includes the element substrate 10, a pixel circuit layer 15, the organic EL element 30, a sealing layer 40, a color filter 50, a filling layer 60, and the protective glass 70.

The element substrate 10 includes a base material 10s. An organic EL element 30, the color filter 50, and the like are formed on the base material 10s of the element substrate 10. The base material 10s is arranged most downwardly in the element substrate 10. In the present embodiment, a silicon substrate is used as the forming material of the base material 10s. Note that, since the organic EL device 100 is a top-emitting structure, an opaque ceramic substrate or a semiconductor substrate may be used for the base material 10s.

On the base material 10s of the element substrate 10A, that is, in the +Z direction, pixel circuit layer 15 of the light-emitting pixel 20 is formed. Although not shown, the pixel circuit layer 15 includes, in addition to the three transistors 21, 22, 23 described above, a reflection electrode, a high reflection layer, and the like.

The reflection electrode is formed above a transistor 21, 22, 23 and the like. The reflection electrode also serves as a power supply line, and is formed from a material having light reflectivity and electrical conductivity. As this material, for example, metal such as Al (aluminum), Ag (silver), Cu (copper), or alloy of these metals can be used, and in the present embodiment, Al is used.

The high reflection layer is a SiO2 (silicon oxide) film formed on the reflection electrode and functions as a high reflection layer that improves light reflectivity. The high reflection layer is also used as a hard mask for patterning in forming the reflection electrode. As a result, in the forming step described above, when the reflection electrode is divided for each light-emitting pixel 20, a groove is formed in the periphery of the light-emitting pixel 20.

Although not shown, a first protective layer, an embedded insulating layer, and a second protective layer are formed on the high reflection layer in this order upward. The first protective layer is a SiN (silicon nitride) film formed on the high reflection layer, and is also formed on the inner surface of the groove that divides the light-emitting pixel 20. The embedded insulating layer is a SiO2 layer for filling and flattening a groove that divides the light-emitting pixel 20. The second protective layer is a flat SiN layer formed on the first protective layer and the embedded insulating layer.

Furthermore, an optical adjustment layer (not illustrated) is formed on the second protective layer. The organic EL device 100 employs a resonance structure that resonates emitted light. By optimizing the optical path length between the reflective layer and the cathode 36 for each of the color light of R, G, B, the resonance structure enhances the emitted light by the interference of light of each color wavelength and improves the light extraction efficiency.

The optical adjustment layer is a part of the adjustment layer for adjusting the length of the optical path in the resonance structure of the organic EL device 100, that is, the optical path length. Specifically, in the light-emitting pixel 20G, one layer of a second optical adjustment layer is formed as an optical adjustment layer on the second protective layer. In the light-emitting pixel 20R, a first optical adjustment layer and the second optical adjustment layer are formed as an optical adjustment layer on the second protective layer. In the light-emitting pixel 20B, the optical adjustment layer is not formed on the second protective layer, and the pixel electrode 31B is formed directly on the second protective layer. The first optical adjustment layer and the second optical adjustment layer are SiO2 films.

The organic EL elements 30 are formed on the pixel circuit layer 15. In the organic EL element 30, the pixel electrode 31, the function layer 35, and the cathode 36 are stacked in this order from the pixel circuit layer 15 side upward.

The pixel electrode 31 is an anode with optical transparency, and is formed of a transparent conductive film having optical transparency and electrical conductivity. In the present embodiment, Indium Tin Oxide (ITO) is used as a preferable example. Here, although not shown, the pixel electrode 31 is divided by the pixel isolation layer corresponding to the opening 29R, 29G, 29B of each of the light-emitting pixels 20. In other words, the pixel isolation layer is formed between the adjacent pixel electrodes 31. The SiO2 is used as the forming material of the pixel isolation layer.

Although not shown, the function layer 35 is an organic light-emitting layer including a hole injection layer (HIL), an organic light-emitting layer (EML), and an electron transport layer (ETL), which are stacked in this order from the pixel electrode 31 side upward.

By applying the driving potential between the pixel electrode 31 and the cathode 36, holes are injected into the function layer 35 from the pixel electrode 31, and electrons are injected into the function layer 35 from the cathode 36. In the organic light-emitting layer included in the function layer 35, the injected holes and electrons form excitons, and when the excitons decay, some of the resulting energy is radiated as fluorescence or phosphorescence. Note that, in addition to the hole injection layer, organic light-emitting layer, and electron transport layer, the function layer 35 may include a hole transport layer, an electron injection layer, or an intermediate layer that improves or controls injectability or transport properties of holes or electrons into the organic light-emitting layer.

When a drive voltage is applied to the organic EL element 30, the organic light-emitting layer emits white light. As a preferable example, white light is obtained by combining the organic light-emitting layers that can obtain light emissions of the R, G, B. Further, a pseudo-white light can be also obtained by combining organic light-emitting layers that can obtain light emissions of B and Y (yellow). The function layer 35 is formed in common over the light-emitting pixels 20R, 20G, 20B.

The cathode 36 is a semi-transmissive reflective common electrode. In the present embodiment, a thin film of a MgAg alloy in which Mg (magnesium) and Ag are co-deposited is used as the cathode 36.

The organic EL element 30 is formed in a region substantially overlapping the display region E in a plan view. The cathode 36 is formed to the outside of the display region E in plan view, and is electrically coupled to the pair of scan line driving circuits 102 described above.

The sealing layer 40 is formed on the cathode 36. The sealing layer 40 includes a first inorganic sealing layer 41, an organic intermediate layer 42, and a second inorganic sealing layer 43. The first inorganic sealing layer 41 is formed by covering the cathode 36 using a forming material having excellent gas barrier properties and transparency. The first inorganic sealing layer 41 is a barrier layer that prevents damage to the function layer 35 when the organic intermediate layer 42 is formed by screen printing and the like. Examples of the forming material of the first inorganic sealing layer 41 include inorganic compounds such as metal oxides such as silicon oxide, silicon nitride, silicon oxynitride, and titanium oxide. In the present embodiment, SiON (silicon oxynitride) is used for the first inorganic sealing layer 41 as a preferable example.

The organic intermediate layer 42 is an organic resin layer having transparency and is formed to cover the first inorganic sealing layer 41. The organic intermediate layer 42 has function of flattening and preventing cracks in the first inorganic sealing layer 41. An epoxy resin is used as a preferable example of the forming material of the organic intermediate layer 42. As the organic intermediate layer 42, the forming material is applied by a printing method or a spin coating method and cured, thereby covering and flattening the uneven shape or foreign matter on the surface of the first inorganic sealing layer 41.

The second inorganic sealing layer 43 is an inorganic compound layer and is formed on the organic intermediate layer 42. The second inorganic sealing layer 43, similar to the first inorganic sealing layer 41, is formed using an inorganic compound having transparency and gas barrier properties having excellent water resistance and heat resistance. The second inorganic sealing layer 43 having function of suppressing moisture and the like from entering the function layer 35. As a result, occurrence of display defects and the like in the organic EL device 100 is suppressed. In the present embodiment, SiON is used for the second inorganic sealing layer 43 as a preferable example.

On the sealing layer 40, the color filter 50, a light shielding layer 53, and a CF (color filter) bank 44 are formed. The color filter 50 is formed on the second inorganic sealing layer 43 whose surface is flattened. The color filter 50 includes filter layers 50R, 50G, 50B corresponding to each of the light-emitting pixels 20R, 20G, 20B, respectively. The filter layers 50R, 50G, 50B are corresponding to the light-emitting pixels 20R, 20G, 20B, respectively. In other words, the filter layers 50R, 50G, 50B are arranged so as to face each pixel electrode 31 in the ±Z direction.

Each filter layer 50R, 50G, 50B is divided by the CF bank 44. The thickness in the ±Z direction of the filter layer 50R, 50G, 50B is not particularly limited, but with respect to the filter layer 50B, the filter layer 50G is formed thin and the filter layer 50R is formed thick. The filter layers 50R, 50G, 50B are formed by applying a photosensitive resin containing a pigment corresponding to each color, and exposing and developing the photosensitive resin.

The color filter 50 is formed in a region substantially overlapping the display region E in plan view. In plan view, a light shielding layer 53 is formed outside the display region E. The light shielding layer 53 is formed by stacking layers of the same forming material as the filter layers 50R, 50G, 50B, facing upward from the base material 10s side. As a result, the light shielding layer 53 has light shielding property. Although not particularly limited, the thickness in the ±Z direction of the light shielding layer 53 may be thicker than the filter layer 50R.

In plan view, the CF bank 44 is also formed further outside the light shielding layer 53. The CF bank 44 is formed using, for example, the photosensitive resin that does not contain a colored material. The CF bank 44 is formed by, for example, applying the photosensitive resin by a spin coating method and the like, the applied photosensitive resin to form a photosensitive resin layer, and then exposing and developing the photosensitive resin layer by a photolithography method. The photosensitive resin may be either a positive type or a negative type. Note that a known configuration and a known manufacturing method can be used for the configuration from the pixel circuit layer 15 to the color filter 50 described above.

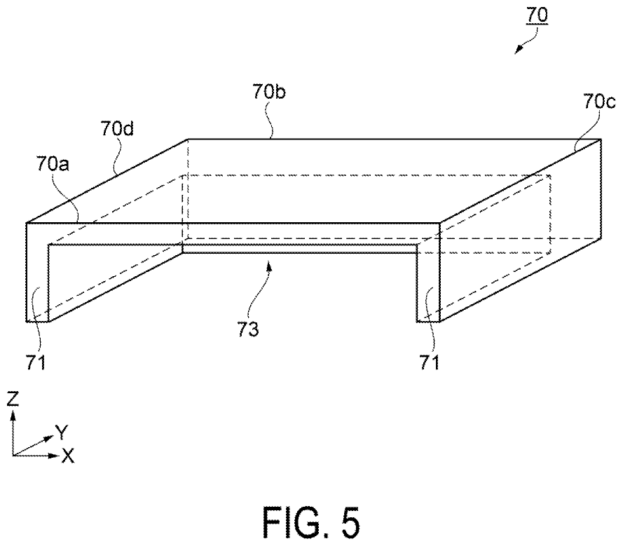

A protective glass 70 is arranged on the element substrate 10 via the filling layer 60. The protective glass 70 covers the upper side and the lateral side of the organic EL element 30 and the like that is formed on the element substrate 10. Here, the form of the protective glass 70 will be described with reference to FIG. 5. FIG. 5 is a perspective view illustrating the appearance of the protective glass.

As illustrated in FIG. 5, the protective glass 70 includes a housing portion 73 that houses the organic EL element 30 and the like. The housing portion 73 includes a wall portion 71 corresponding to three sides of the second side portion 70b, the third side portion 70c, and the fourth side portion 70d of the outer edge of the protective glass 70. Specifically, the wall portion 71 extends from the flat plate shaped main body of the protective glass 70 arranged along the XY plane along the −Z direction, which is the normal line direction of the element substrate 10. In contrast, to the first side portion 70a of the outer edge of the protective glass 70, no corresponding wall portion 71 is disposed.

In other words, the housing portion 73 is formed from a main body of the protective glass 70 and the wall portion 71. In the housing portion 73, the −Z direction and the −Y direction are open. Thus, when the organic EL device 100 is assembled, in the −Y direction of the housing portion 73, a region of the element substrate 10 protrudes, in which a part of the data line driving circuit 101, the control circuit 105, and the external connection terminal 103 are formed.

The protective glass 70 is not particularly limited, but for example, the length of the first side portion 70a and the second side portion 70b is about 13 mm, the length of the third side portion 70c and the fourth side portion 70d is about 8 mm, and the length along the Z axis, which is the height of the wall portion 71, is about 2 mm.

For the protective glass 70, for example, a transparent substrate such as a glass substrate, a quartz substrate and the like is used. In the present embodiment, a quartz substrate is used as a preferable example in the protective glass 70. Known processing methods can be employed as the forming method of the protective glass 70. Specifically, for example, after a plurality of housing portions 73 are formed using a photolithography method and the like, with respect to the quartz substrate of a large size, and then divided into individual protective glass 70. Note that, the surface of the +Z direction of the housing portion 73 is flattened by performing a chemical mechanical polishing (CMP) processing and the like.

Returning to FIG. 4, a filling layer 60, which is an organic resin layer having adhesiveness and transparency, is interposed between the housing portion 73 of the protective glass 70 and the element substrate 10. In other words, the filling layer 60 is filled between the housing portion 73 and the upper side and the lateral side of the element substrate 10, and the protective glass 70 and the element substrate 10 are bonded together. Specifically, the filling layer 60 covers the upper side of the color filter 50 and the light shielding layer 53. In addition, the filling layer 60 also covers the lateral side of the CF bank 44 and the sealing layer 40 outside the light shielding layer 53 and a part of the pixel circuit layer 15 exposed to the upper side and the lateral side. In other words, what bonded to the protective glass 70 by the filling layer 60 is an organic EL element 30, a color filter 50, and a sealing layer 40 formed on the element substrate 10 and the like. Note that “lateral side” refers to a direction orthogonal to the ±Z direction.

As a method of forming the filling layer 60, for example, an uncured adhesive is applied to the individual element substrates 10 and bonded to the protective glass 70, and the element substrate 10 and the protective glass 70 are crimped with an appropriate force. In a typical organic EL device, during the aforementioned crimping, foreign matter such as a sandwiched glass sheet may be pushed into the element substrate 10 side, causing damage to the color filter and the lower wiring layer. In the organic EL device 100 of the present embodiment, sandwiching of the glass sheet is suppressed, so even if the element substrate 10 and the protective glass 70 are crimped with an uncured adhesive interposed therebetween, damage to the color filter 50 and the underlying wiring layer is prevented.

By crimping, the uncured adhesive spreads across the gap between the element substrate 10 and the protective glass 70, and the gap is filled with the uncured adhesive. Thereafter, the uncured adhesive is reactively cured by heat or ultraviolet light, or the like to form the filling layer 60. The adhesive that is the forming material of the filling layer 60 is not particularly limited, but a known adhesive can be used. In the present embodiment, an epoxy resin having curability is used as a preferable example.

When the organic EL device 100 is viewed in side view from the −Y direction, a lower end 71B of the wall 71 is at a position substantially equal to the bottom surface 10F of the element substrate 10 in the ±Z direction. Here, the bottom surface 10F refers to a surface on the opposite side of the base material 10s on which the organic EL element 30 is formed.

The position of the lower end 71B in the ±Z direction is not limited to the above, and may be positioned on the side of the bottom surface 10F than the surface of the element substrate 10 on which the organic EL element 30 is formed, that is, the surface above the base material 10s. In other words, the lower end 71B may be arranged in the −Z direction than the pixel circuit layer 15. Thus, when the element substrate 10 and the protective glass 70 are bonded via the filling layer 60, even if a glass sheet is generated from the outer edge, side surface, or the like of the protective glass 70, the glass sheet can be prevented from being sandwiched between the filling layer 60 and the protective glass 70.

Here, as described above, the housing portion 73 of the protective glass 70 is open without the wall portion 71 in the −Y direction. Therefore, although not shown, on the −Y direction side of the organic EL device 100, the side surface of the CF bank 44 is covered by the filling layer 60 from the pixel circuit layer 15, and the filling layer 60 is exposed in the −Y direction. Note that in the housing portion 73, a wall portion corresponding to the first side portion 70a and not interfering with the data line driving circuit 101 or the control circuit 105 may be disposed and cover a part of the side surface of the filling layer 60 in the −Y direction.

The organic EL device 100 is a top-emitting structure, and light emission is extracted from the +Z direction of the protective glass 70. Light emitted from the function layer 35 of the organic EL element 30 is transmitted through any of the corresponding filter layers 50R, 50G, 50B and is emitted from the protective glass 70 side.

According to the present embodiments, the following advantages can be obtained.

In the organic EL device 100, occurrence of a wiring short-circuit failure due to the glass sheet from the protective glass 70 can be suppressed. Specifically, in plan view, three sides of the second side portion 70b, the third side portion 70c, and the fourth side portion 70d, which are the outer edges of the protective glass 70, are arranged outside than the second side portion 10b, the third side portion 10c, and the fourth side portion 10d, which are corresponding three sides of the outer edges of the element substrate 10. Therefore, even if the glass sheet is generated from the outer edge of the protective glass 70 and the like, the glass sheet is suppressed from being sandwiched between the protective glass 70 and the element substrate 10. As a result, the organic EL device 100 in which the occurrence of wiring short-circuit failure is suppressed as compared with the known device can be provided.

Since the lateral side of the three sides of the organic EL element 30 is covered by the wall portion 71, foreign matter such as the glass sheet is less likely to be sandwiched between the protective glass 70 and the element substrate 10.

Because the occurrence of wiring short-circuit failure is suppressed, the yield in the manufacturing process of the organic EL device 100 can be improved.

### 2. Second Embodiment

In the present embodiment, an organic EL device as a light-emitting device is exemplified in the same manner as in the first embodiment. The light-emitting device can also be suitably used in the HMD described below. Note that the organic EL device of the present embodiment differs from the organic EL device 100 of the first embodiment in the form of the protective glass and the base material of the element substrate. In addition, the same components as in the first embodiment are given the same reference signs, and redundant descriptions of these components will be omitted.

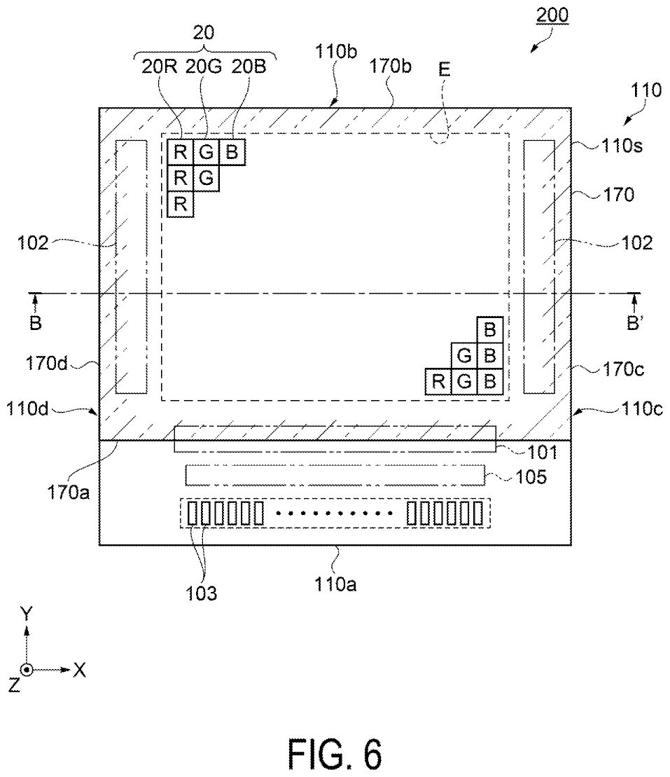

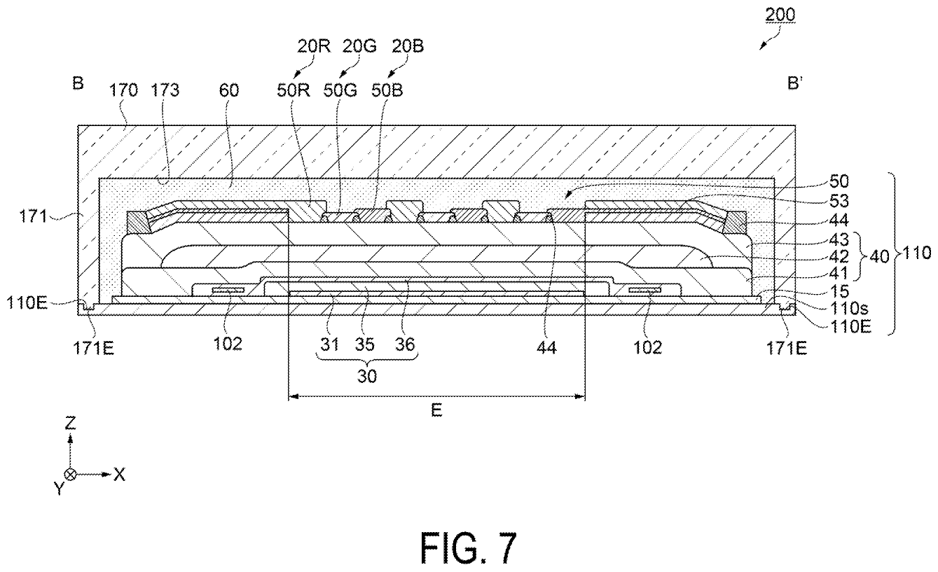

A configuration of the organic EL device as the light-emitting device according to the present embodiment will be described with reference to FIG. 6 and FIG. 7. FIG. 6 is a schematic plan view illustrating a configuration of an organic EL device according to a second embodiment. FIG. 7 is a schematic cross-sectional view illustrating the configuration of the organic EL device.

Here, FIG. 7 illustrates a cross section taken along the XZ plane including line B-B′ in FIG. 6, and is a cross-sectional view when viewed from the −Y direction orthogonal to the normal line direction of the element substrate 110. In addition, in FIG. 7, for convenience of illustration, the number of light-emitting pixels 20 is smaller than the actual number, and the display region E is smaller than the actual size. Furthermore, in FIG. 7, the illustration of the first transistor 21, the second transistor 22, and the third transistor 23 are omitted.

As illustrated in FIG. 6, an organic EL device 200 as a light-emitting device includes an element substrate 110 as a substrate, a plurality of light-emitting pixels 20, a protective glass 170, a data line driving circuit 101, a pair of scan line driving circuits 102, a control circuit 105, and a plurality of external connection terminals 103. Here, in FIG. 6, with respect to the element substrate 110, the vicinity of an outer edge of the protective glass 170 arranged above is shown by hatching, and the protective glass 170 is shown transparent.

The element substrate 110 is substantially rectangular in plan view, and has four sides of the outer edge, a first side portion 110a, a second side portion 110b, a third side portion 110c, and a fourth side portion 110d. The first side portion 110a and the second side portion 110b are along the X axis and opposite to each other in the ±Y direction. The first side portion 110a is a side closer to the −Y direction among the four sides of the outer edge. The second side portion 110b is a side closer to the +Y direction among the four sides of the outer edge. The third side portion 110c and the fourth side portion 110d are along the Y axis and opposite to each other in the ±X direction. The third side portion 110c is a side closer to the +X direction among the four sides of the outer edge. The fourth side portion 110d is a side closer to the −X direction among the four sides of the outer edge.

The protective glass 170 is substantially rectangular in plan view, and has four sides of the outer edge, a first side portion 170a, a second side portion 170b, a third side portion 170c, and a fourth side portion 170d. The first side portion 170a and the second side portion 170b are along the X axis and opposite to each other in the ±Y direction. The first side portion 170a is a side closer to the −Y direction among the four sides of the outer edge. The second side portion 170b is a side closer to the +Y direction among the four sides of the outer edge. The third side portion 170c and the fourth side portion 170d are along the Y axis and opposite to each other in the ±X direction. The third side portion 170c is a side closer to the +X direction among the four sides of the outer edge. The fourth side portion 170d is a side closer to the −X direction among the four sides of the outer edge.

The protective glass 170 is arranged covering the upper side of the display region E. In plan view, three sides of the outer edge of the protective glass 170 are arranged to overlap with corresponding three of the outer edges of the element substrate 10. Specifically, three sides of the second side portion 170b, the third side portion 170c, and the fourth side portion 170d among the four outer edges of the protective glass 170 overlap with the second side portion 110b, the third side portion 110c, and the fourth side portion 110d among the four the outer edges of the element substrate 110 in plan view. The first side portion 110a of the element substrate 110 protrudes outward beyond the first side portion 170a of the protective glass 170 in a plan view. Therefore, a part of the data line driving circuit 101, the control circuit 105, and the external connection terminal 103 arranged on the element substrate 110 are not covered with the protective glass 170 and are exposed upward.

As illustrated in FIG. 7, the organic EL device 200 includes the element substrate 110, a pixel circuit layer 15, the organic EL element 30, a sealing layer 40, a color filter 50, a filling layer 60, and the protective glass 170.

The element substrate 110 includes a base material 110s. The light-emitting pixels 20B, 20G, 20B that include the organic EL element 30, the color filter 50, and the like are formed on the base material 110s of the element substrate 110. The base material 110s is arranged most downwardly in the element substrate 110. In the present embodiment, a silicon substrate is used as the forming material of the base material 110s.

The organic EL element 30 as the light-emitting element is formed on the base material 110s of the element substrate 110. The protective glass 170 is arranged covering the organic EL element 30. The filling layer 60 is interposed between the protective glass 170 and the element substrate 110, and bonds the protective glass 170 and the element substrate 110 together. The protective glass 170 includes a housing portion 173 that houses the organic EL element 30 and the like. The housing portion 173 includes a wall portion 171 corresponding to three sides of the second side portion 170b, the third side portion 170c, and the fourth side portion 170d of the outer edge of the protective glass 170 in plan view. Specifically, the wall portion 171 extends from the flat plate shaped main body of the protective glass 170 arranged along the XY plane along the −Z direction, which is the normal line direction of the element substrate 110. In contrast, although not shown, to the first side portion 70a of the outer edge of the protective glass 70, no corresponding wall portion 71 is disposed.

In other words, the housing part 173 is formed from a main body of the protective glass 170 and the wall portion 171. In the housing portion 173, the −Z direction and the −Y direction are open in order to protrude the external connection terminals 103 and the like of the element substrate 110 from the protective glass 170.

A protruding convex pattern 171E facing downward is disposed on the lower end of the wall portion 171 of the protective glass 170. Corresponding to the convex pattern 171E, a concave pattern 110E is disposed on the base material 110s of the element substrate 110. Specifically, the concave pattern 110E is a concave shape facing upward, and is disposed at a position corresponding to the convex pattern 171E on the surface above the base material 110s, that is, the surface on which the organic EL element 30 and the like are formed. Because the convex pattern 171E and the concave pattern 110E are fitted, the positioning of the cover glass 170 with respect to the element substrate 110 is completed.

The convex pattern 171E may be disposed on all of the wall portions 171 corresponding to three sides of the second side portion 170b, the third side portion 170c, and the fourth side portion 170d, or may be disposed on only a part of the wall portion 171. In other words, the convex pattern 171E and the concave pattern 110E may be disposed corresponding to some or all of the three sides of the second side portion 170b, the third side portion 170c, and the fourth side portion 170d of the protective glass 170 in plan view.

The protective glass 170 can use the same forming material and processing method as those of the protective glass 70 of the first embodiment. Similar to the housing portions 73, the convex pattern 171E can be formed using a photolithography method and the like.

The base material 110s can use the same forming material and processing method as those of the base material 10s of the first embodiment. In the present embodiment, a silicon substrate is used as the forming material of the base material 110s. Thus, the concave pattern 110E of the base material 110s is also formed by silicon that is the same material as the base material 110s. A known processing method can be used for forming the concave pattern 110E, and although not particularly limited, for example, wet etching using a hard mask is used.

According to the present embodiments, the following advantages can be obtained in addition to the advantages described above.

In the manufacturing process of the organic EL device 200, the convex pattern 171E and the concave pattern 110E are fitted, so the positioning of the element substrate 110 and the protective glass 170 can be facilitated. Furthermore, since the positional deviation between the element substrate 110 and the protective glass 170 is suppressed, the assembly accuracy of the organic EL device 200 can be improved.

### 3. Third Embodiment

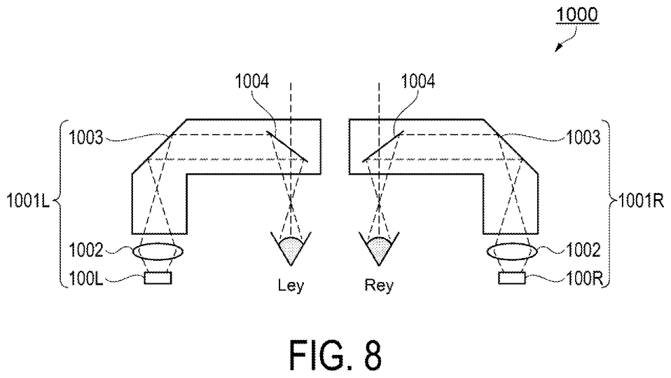

According to the electronic device of the present embodiment, a head-mounted display will be described as an example of the electronic apparatus. FIG. 8 is a schematic diagram illustrating a head-mounted display as an electronic apparatus according to a third embodiment.

As illustrated in FIG. 8, the head-mounted display 1000 of the present embodiment includes a pair of optical units 1001L, 1001R. Furthermore, although not shown, the head-mounted display 1000 includes a power supply unit and a control unit, a mounting unit for mounting the head-mounted display 1000 on the head of a user, and the like. A pair of optical units 1001L, 1001R display information corresponding to the left and right eyes of the user. Here, the pair of optical units 1001L and 1001R are configured to be horizontally symmetrical, and thus the optical unit 1001R, configured for the right eye Rey, will be described as an example.

The optical unit 1001R includes a display portion 100R, a condensing optical system 1002, and a curved light guide 1003. The condensing optical system 1002 and the light guide 1003 are arranged in this order in the traveling direction of the display light emitted from the display unit 100R. A half mirror layer 1004 is provided in the light guide 1003. With this arrangement, in the optical unit 1001R, the display light emitted from the display unit 1001R enters the light guide 1003 via the condensing optical system 1002, and the display light is reflected by the half mirror layer 1004, and is guided to the right eye Rey.

The display unit 100R can display a display signal transmitted from the control unit as image information such as text, and video. The image information displayed on the display unit 100R is converted from a real image to a virtual image by the condensing optical system 1002 and enters the light guide 1003. The organic EL device 100 of the above embodiment is applied to the display unit 100R.

The light guide 1003 is configured by combining rod lenses, and forms a rod integrator. The display light incident on the light-guiding body 1003 is totally reflected within the rod lens and transmitted to the half mirror layer 1004. The half mirror layer 1004 is arranged at an angle that reflects the luminous flux of the display light toward the right eye Rey.

The image that is the display light incident on the half mirror layer 1004 is a virtual image. As a result, the user can visually recognize both the virtual image projected on the display unit 100R and the external scene of the half mirror layer 1004. That is, the head-mounted display 1000 is a see-through type projection display device.

Similar to the optical unit 1001R for the right eye computing device, the optical unit 1001L for the left eye Ley includes a display unit 100L to which the organic EL device 100 of the embodiment described above is applied. The configuration and function of the optical unit 1001L are the same as the optical unit 1001R for the right eye Rey. Therefore, description of the optical unit 1001L is omitted.

According to the present embodiment, since the organic EL device 100, which is the light-emitting device of the above-described embodiment, is mounted, the occurrence of wiring short-circuit failure in the organic EL device 100 can be suppressed, and the head-mounted display 1000 having improved reliability can be provided.

The head mounted display 1000 on which the organic EL device 100 of the embodiment is mounted is not limited to a configuration including a pair of optical units 1001L and 1001R corresponding to both eyes. The head mounted display 1000 may be configured to include one of the optical unit 1001R or the optical unit 1001L, for example. In addition, the head mounted display 1000 is not limited to being a see-through type, and may be an immersive type that visually recognizes an image in a state in which external light is blocked.

The electronic apparatus in which the organic EL device 100 of the embodiment is mounted is not limited to the head mounted display. The organic EL device 100 of the embodiment can be suitably used as a display unit such as another wearable device such as a smart watch, a head-up display (HUD), an electronic viewfinder (EVF), and a portable information terminal.

### 4. First Modified Example

In the present modified example, the organic EL device as the light-emitting device is exemplified in the same manner as those in the first embodiment. In the organic EL device 100 of the first embodiment, the height in the ±Z direction between the lower end 71B of the protective glass 70 and the bottom surface 10F of the element substrate 10 is the same, but it is not limited thereto.

In the organic EL device according to the first modified example, with respect to the height of the organic EL device 100 of the first embodiment, the height of the wall portion of the protective glass in the ±Z direction is different. In addition, the same components as in the first embodiment are given the same reference signs, and redundant descriptions of these components will be omitted.

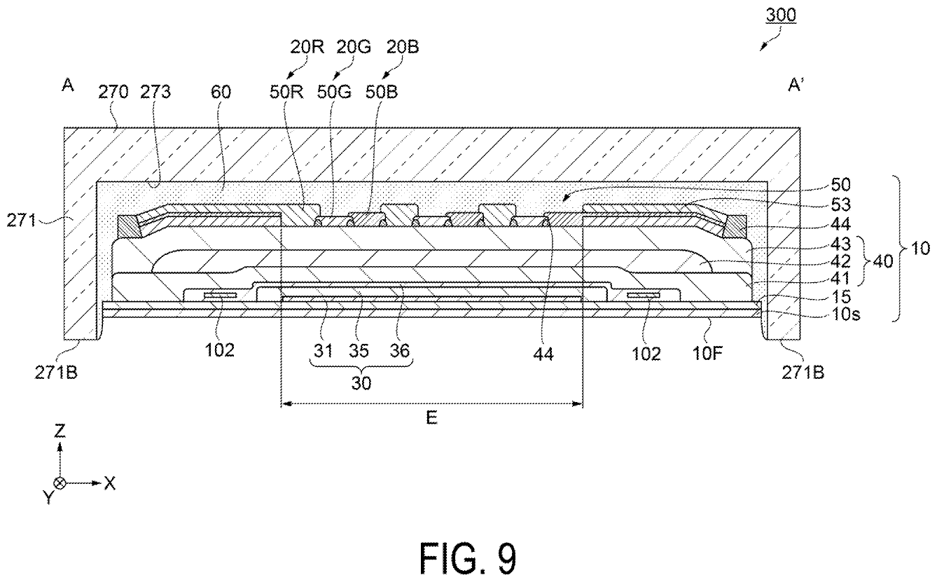

The configuration of the organic EL device as the light-emitting device according to the present modified example will be described with reference to FIG. 9. FIG. 9 is a schematic cross-sectional view illustrating a configuration of an organic EL device as a light-emitting device according to a first modified example. FIG. 9 illustrates a cross section corresponding to FIG. 4 in the first embodiment.

As illustrated in FIG. 9, the organic EL device 300 of the present modified example includes an element substrate 10, a filling layer 60, a protective glass 270, and the like.

The protective glass 270 includes a housing portion 273 that houses the organic EL element 30 and the like. Similar to the housing portion 73 of the first embodiment, the housing portion 273 includes a wall portion 271 corresponding to three sides of the second side portion, the third side portion, and the fourth side portion that are not illustrated. Specifically, the wall portion 271 extends from the flat plate shaped main body of the protective glass 270 arranged along the XY plane along the −Z direction, which is the normal line direction of the element substrate 10. In contrast, to the first side portion which is not shown of the outer edge of the protective glass 270, no corresponding wall portion 271 is disposed.

When the organic EL device 300 is viewed as a side from the −Y direction, the lower end 271B of the wall 271 is separated from the bottom surface of the element substrate 10 with respect to the surface of the element substrate 10 on which the organic EL element 30 is formed. In other words, in the ±Z direction, the bottom end 271B of the wall 271 is positioned below the bottom surface 10F of the element substrate 10. That is, in the ±Z direction, the length of the wall portion 271 of the present modified example is formed longer than the length of the wall portion 71 of the first embodiment, and only this point is different from the first embodiment.

Note that since the wall portion 271 extends below the bottom surface 10F of the element substrate 10, the filling layer 60 may partially protrude from the gap between the wall portion 271 and the element substrate 10.

According to this modified example, even if the glass sheet is generated from the lower end 271B of the wall portion 271, it is difficult to sandwich the glass between the protective glass 270 and the element substrate 10.

### 5. Second Modified Example

In the present modified example, the organic EL device as the light-emitting device is exemplified in the same manner as those in the first embodiment. In the first embodiment, the protective glass 70 whose main body is a flat plate is exemplified, but it is not limited to this, and the protective glass may have a shape having a curved surface in the main body. In the organic EL device according to the second modified example, the shape of the protective glass is different with respect to the organic EL device 100 of the first embodiment.

The organic EL device of the second modified example includes a microlens array for collecting light on the main body of the protective glass. Specifically, the organic EL device of the present modified example uses a top emission structure in the same manner as the organic EL device of the embodiment described above. In other words, light emission is extracted from the protective glass side with respect to the element substrate. In the present modified example, the microlens array is disposed in the plane of the main body of the protective glass that is the emission side of the light.

The microlens array of the present modified example includes a plurality of microlenses. The plurality of microlenses are arranged so as to overlap with the light-emitting pixels of the organic EL device in plan view, and are arranged in a matrix corresponding to a plurality of light-emitting pixels. The plurality of microlenses are each formed into a convex shape. The microlens array may be formed by processing the protective glass, or may be manufactured separately from the protective glass and then incorporated into the protective glass.

According to the present modified example, the protective glass includes a microlens array, and thus the light emitted from the light-emitting pixels can be collected and used.

### 6. Third Modified Example

In the present modified example, the organic EL device as the light-emitting device is exemplified in the same manner as those in the first embodiment. In the organic EL device 100 of the first embodiment, a configuration including a color filter 50 is exemplified, but it is not limited thereto. The color filter 50 is not necessarily required, and the organic EL device according to the present modified example does not include a color filter 50.

### 7. Fourth Modified Example

In the present modified example, the organic EL device as the light-emitting device is exemplified in the same manner as those in the first embodiment. The protective glass 70 included in the organic EL device 100 of the first embodiment has the wall portion 71, but it is not limited thereto.

The protective glass of the organic EL device according to this modification is arranged so that three sides of the outer edge do not overlap the element substrate 10, but is formed on a flat plate without the wall portion. According to this, in the manufacturing step of the organic EL device, the step of forming the housing portion can be omitted.

### 8. Fifth Modified Example

In the present modified example, the organic EL device as the light-emitting device is exemplified in the same manner as those in the first embodiment. In the protective glass 70 of the organic EL device 100 according to the first embodiment, the lower end 71B of the wall portion 71 is positioned at substantially the same position as the bottom surface 10F of the element substrate 10 in the ±Z directions, but it is not limited thereto.

In the protective glass of the organic EL device according to the present modified example, the lower end of the wall portion is positioned above the bottom face 10F.

Contents derived from the Embodiments will be described below.

A light-emitting device includes a substrate, a light-emitting element arranged at the substrate a protective glass covering the light-emitting element, and a filling layer that bonds the protective glass and the substrate, wherein, three sides of an outer edge of the protective glass are arranged so as not to overlap the substrate in plan view.

According to this configuration, in the light-emitting device, occurrence of a wiring short-circuit failure due to the glass sheet from the protective glass can be suppressed. Specifically, three sides of the outer edge of the protective glass are arranged so as not to overlap the element substrate in plan view. Therefore, even if the glass sheet is generated from the outer edge of the protective glass and the like, it is suppressed that the glass sheet is sandwiched between the protective glass and the substrate. As a result, a light-emitting device having a wiring short-circuit failure less than that of typical light-emitting devices can be provided.

In the light-emitting device described above, the protective glass may include a housing portion that houses the light-emitting element, and the housing portion may include the wall portion corresponding to three sides of the protective glass.

According to this configuration, the light-emitting element is covered by the wall portion of the housing portion, so it is difficult for a foreign matter such as a glass sheet to be pinched between the protective glass and the substrate. Accordingly, occurrence of wiring short-circuit failure and the like in the light-emitting device can be further suppressed.

In the light-emitting device described above, the wall portion extends along the normal line direction of the substrate, and when viewed as a side from a direction orthogonal to the normal line direction, the bottom end of the wall portion may be positioned on the side of the bottom surface opposite to the surface on which the light-emitting element is formed than the surface on which the light-emitting element is formed.

According to this configuration, since the lateral side of the light emitting element is covered by the wall portion, it becomes more difficult for foreign matter such as glass pieces to be further sandwiched between the protective glass and the substrate.

In the light-emitting device described above, in side view, the lower end of the wall portion may be separated from the bottom surface with respect to the surface on which the light-emitting element is formed on the substrate.

According to this configuration, the lateral side of the light-emitting element and the substrate is covered by the wall portion. Therefore, as compared with a case where the lateral side of the substrate is not covered by the wall portion, it is difficult for a foreign material such as a glass sheet to be pinched between the protective glass and the substrate. In particular, even if the glass sheet is generated from the lower end of the wall portion, it is difficult to sandwich the glass between the protective glass and the element substrate.

A light-emitting device includes a substrate, a light-emitting element arranged at the substrate, a protective glass covering the light-emitting element, and a filling layer that bonds the protective glass and the substrate, wherein, the protective glass includes a housing part that houses the light-emitting element, the housing part includes a wall portion corresponding to the three sides of the outer edge of the protective glass in plan view, the wall portion extends along a thickness direction of the substrate, a lower end of the wall portion is provided with a convex pattern, a concave pattern that fits the convex pattern is provided at a surface of the substrate at which the light-emitting element is arranged.

According to this configuration, in the light-emitting device, occurrence of a wiring short-circuit failure due to the glass sheet from the protective glass can be suppressed. Specifically, the lateral side of the light-emitting element is covered by the wall portion of the storage portion, so that it becomes difficult for foreign matter such as glass pieces to be caught between the protective glass and the substrate.

Accordingly, occurrence of wiring short-circuit failure and the like in the light-emitting device can be further suppressed.

In the light-emitting device described above, the concave pattern may be formed from the same material as a material of the substrate.

According to this configuration, by forming the substrate and the concave pattern of the same material, it is possible to integrally form the substrate and the concave pattern.

An electronic apparatus according to the present disclosure includes the light-emitting device described above.

According to this configuration, by including the light-emitting device in which the occurrence of wiring short-circuit defects is suppressed, an electronic device with improved reliability can be provided.

What is claimed is:

1. A light-emitting device comprising:
a first substrate;
a light-emitting element arranged on the first substrate;
a second substrate covering the light-emitting element; and
a filling layer that bonds the second substrate and the first substrate, wherein,
in plan view, a first side of an outer edge of the second substrate, a second side of the outer edge of the second substrate, and a third side of the outer edge of the second substrate are do not overlap with the first substrate.

2. The light-emitting device according to claim 1, wherein
the second substrate includes a housing portion that houses the light-emitting element,
the housing portion includes a wall portion corresponding to the first side, the second side, and the third side of the second substrate.

3. The light-emitting device according to claim 2, wherein
the wall portion extends along a thickness direction of the first substrate,
in plan view from the thickness direction, a lower end of the wall portion is positioned on an opposite-side from a first surface of the first substrate, at which the light-emitting element is arranged, from the light-emitting element.

4. The light-emitting device according to claim 3, wherein
a distance in the thickness direction between the lower end of the wall portion and the first surface is greater than a thickness of the first substrate.

5. A light-emitting device comprising:
a first substrate;
a light-emitting element arranged on the first substrate;
a second substrate covering the light-emitting element; and
a filling layer that bonds the second substrate and the first substrate, wherein,
the second substrate includes a housing portion that houses the light-emitting element,
the housing portion includes a wall portion corresponding to the three sides of an outer edge of the second substrate in plan view,
the wall portion extends along a thickness direction of the first substrate,
a lower end of the wall portion is provided with a convex pattern,
a concave pattern that fits the convex pattern is provided at a surface of the first substrate at which the light-emitting element is arranged.

6. The light-emitting device according to claim 5, wherein
the concave pattern includes the same material as a material of the first substrate.

7. An electronic apparatus comprising the light-emitting device according to claim 1.
